(19) United States
(12) Patent Application Publication
(10) Pub. No.: US 2026/0239801 A1
(43) Pub. Date: Aug. 13, 2026

(54) LIGHT EMITTING MODULE

(71) Applicant: Seoul Semiconductor Co., Ltd., Ansan-si (KR)

(72) Inventor: Chunghoon Lee, Ansan-si (KR)

(21) Appl. No.: 19/454,281

(22) Filed: Jan. 20, 2026

Related U.S. Application Data
(60) Provisional application No. 63/749,053, filed on Jan. 24, 2025.
(60) Provisional application No. 63/867,036, filed on Aug. 20, 2025.

(51) Int. Cl. H10H 29/855

(52) U.S. Cl. CPC H10H 29/8552

(57) ABSTRACT

A light emitting module including a substrate, a plurality of light emitting devices disposed on one surface of the substrate, and a low-transmittance layer disposed on a light-exiting surface side of the substrate, in which the low-transmittance layer includes a low-transmittance region having a light transmittance of less than 50% and a light transmitting region having a light transmittance higher than that of the low-transmittance region.

### CROSS REFERENCE TO RELATED APPLICATIONS

This application claims priority from and the benefit of U.S. Provisional Patent Application No. 63/749,053, filed on Jan. 24, 2025 and U.S. Provisional Patent Application No. 63/867,036, filed on Aug. 20, 2025, each of which is hereby incorporated by reference for all purposes as if fully set forth herein.

### BACKGROUND

### Field

Embodiments of the invention relate generally to a light emitting module including a light emitting device.

### Discussion of the Background

A light emitting diode (LED) is one of light emitting devices that emit light when current is applied. Recently, the light emitting diode has been widely used in various technical fields such as display apparatuses, vehicle lamps, and general lighting. Moreover, the light emitting diode has advantages of long life, low power consumption, and fast response speed. As such, the light emitting diode has been rapidly replacing a conventional light source. For example, a display apparatus using the light emitting diode may be obtained by forming structures of individually grown red R, green G, and blue B light emitting diodes (LEDs) on a final substrate.

Recently, as the real world and AI technology are combined, there is a growing demand for mirror displays that can reflect real objects while simultaneously displaying digital information or external displays that are installed on building exterior walls or transparent glass to display digital information, and the need for the development of light emitting modules that can be effectively applied to such display apparatuses is also increasing.

The above information disclosed in this Background section is only for understanding of the background of the inventive concepts, and, therefore, it may contain information that does not constitute prior art.

### SUMMARY

A light emitting module according to embodiments of the invention is capable of implementing shapes or letters on a mirror, an exterior, glass, or others.

A light emitting module according to embodiments of the invention is also capable of implementing a clear image by improving a contrast ratio.

A light emitting module according to embodiments of the invention is further capable of improving visibility by improving reflectance.

A light emitting module according to embodiments of the invention is further capable of providing clear image quality without image distortion.

A light emitting module according to embodiments of the invention is also capable of displaying accurate colors by improving color reproducibility.

A light emitting module according to embodiments of the invention is further capable of improving surface quality such as surface flatness, bonding, curvature, reflection, or others.

A light emitting module according to embodiments of the invention is further capable of increasing light extraction efficiency.

Additional features of the inventive concepts will be set forth in the description which follows, and in part will be apparent from the description, or may be learned by practice of the inventive concepts.

A light emitting module according to an embodiment of the present invention includes a substrate, a plurality of light emitting devices disposed on one surface of the substrate, and a low-transmittance layer disposed on a light-exiting surface side of the substrate.

The light transmitting region may be a region in which a perforation passing through the low-transmittance layer is formed.

A cross-sectional diameter of the perforation may be greater than or equal to 50% and less than or equal to 90% of a cross-sectional length of the light emitting device.

The low-transmittance region and the light transmitting region may have different reflectances.

The light transmitting region may be positioned at a position overlapped with the light emitting device.

The low-transmittance layer may be disposed on the other surface of the substrate.

The light emitting module may further include a reflective layer disposed on the plurality of light emitting devices on one side of the substrate.

The light emitting module may further include an optical layer covering the plurality of light emitting devices.

The reflective layer may be disposed on the optical layer.

The light emitting module may further include an optical layer disposed on the plurality of light emitting devices.

The optical layer may include a first optical layer covering the light emitting device and a second optical layer surrounding the first optical layer.

A boundary surface where the first optical layer and the second optical layer meet may be a reflection surface on which emitted light emitted from the light emitting device is reflected.

The first optical layer and the second optical layer may have different optical characteristics.

A reflectance of the second optical layer may be greater than that of the first optical layer.

A cross-sectional width of the first optical layer may vary depending on a distance from one surface of the substrate.

A light emitting module according to an embodiment of the present invention may include a substrate, a plurality of light emitting devices disposed on one surface of the substrate, and a low-transmittance layer including a plurality of perforations disposed on one surface of the substrate and exposing the plurality of light emitting devices.

An optical layer may be disposed within the perforation.

A light-exiting surface of the optical layer may be curved.

A cross-sectional width of the perforation may vary depending on a distance from one surface of the substrate.

A light emitting module according to an embodiment of the present invention may include a substrate, a plurality of light emitting devices disposed on one surface of the substrate, and a low-transmittance layer including a plurality of perforations disposed on one surface of the substrate and exposing the plurality of light emitting devices.

The substrate may include a sidewall portion forming a cavity in which the plurality of light emitting devices is located.

The low-transmittance layer may be disposed on the sidewall portion.

The light emitting module may further include a side reflective layer disposed on an inner surface of the cavity.

The side reflective layer may be a DBR layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a view schematically illustrating a light emitting system according to an embodiment of the invention.

FIG. 2 is a view schematically illustrating a light emitting system according to another embodiment of the invention.

FIG. 3 is a cross-sectional view illustrating a light emitting module according to a first embodiment of the invention.

FIG. 4 is a cross-sectional view illustrating a light emitting module according to a second embodiment of the invention.

FIG. 5 is a cross-sectional view illustrating a light emitting module according to a third embodiment of the invention.

FIG. 6 is a cross-sectional view illustrating a light emitting module according to a fourth embodiment of the invention.

FIG. 7 is a cross-sectional view illustrating a light emitting module according to a fifth embodiment of the invention.

FIG. 8 is a cross-sectional view illustrating a light emitting module according to a sixth embodiment of the invention.

FIG. 9 is a cross-sectional view illustrating a light emitting module according to a seventh embodiment of the invention.

FIG. 10 is a cross-sectional view illustrating a light emitting module according to an eighth embodiment of the invention.

FIG. 11A is a plan view showing a low-transmittance layer according to an embodiment of the invention.

FIG. 11B is a plan view showing a low-transmittance layer according to another embodiment of the invention.

FIG. 12 is a schematical view illustrating a distance relationship between a light emitting system including a light emitting module and a user according to an embodiment.

FIG. 13 is a schematical view illustrating a dimensional design of a low-transmittance layer according to the distance relationship of FIG. 12.

### DETAILED DESCRIPTION

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting module according to embodiments of the invention will be described in detail with reference to the attached drawings.

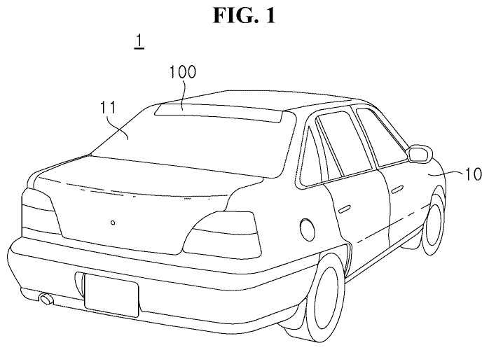

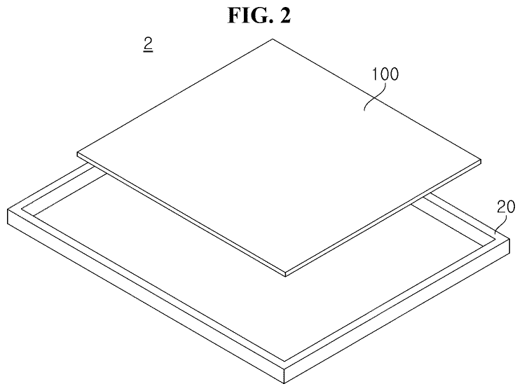

The light emitting module according to embodiments of the invention may be applied to various light emitting systems. FIGS. 1 and 2 schematically illustrate light emitting systems including the light emitting module according to embodiments of the invention.

Referring to FIG. 1, a light emitting system 1 according to an embodiment is a vehicle light emitting system, and a light emitting module 100 may be disposed on one side of a light transmitting portion 11 disposed in one region of a vehicle frame 10. For example, the light emitting module 100 may be a high mounted stop lamp (HMSL) installed in a vehicle. In this case, the light emitting system 1 may have different transmittances in a region where the light emitting module 100 is disposed and in the light transmitting portion 11. Alternatively, the light emitting module 100 may be configured as a display, a headlamp, a high mounted stop lamp, an interior light, or others installed in a vehicle.

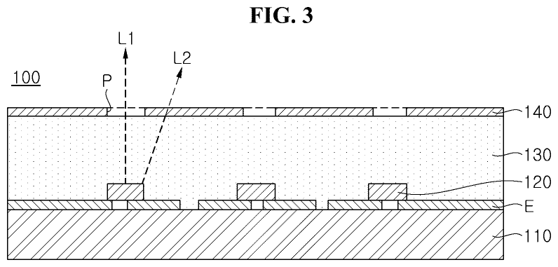

Referring to FIG. 3, a light emitting system 2 according to another embodiment may be a display apparatus. Alternatively, the light emitting system 2 may be a lighting apparatus, translucent glass, smart glass, smart mirror, electronic picture frame, and the like. In this case, the light emitting system 2 may further include a frame 20 that protects the light emitting module 100. To increase a transparency of the light emitting system 2, power may be supplied to the light emitting module 100 by a wire disposed in one region of the frame 20.

The light emitting system 2 may include one or more optical sheets. The light emitting system 2 may include a plurality of optical sheets, and the optical sheets may include at least one of a diffusion sheet, a light collection sheet, or a protection sheet. Each of the optical sheets may include one or a plurality of diffusion sheets, light collection sheets, and protection sheets. Alternatively, each of the optical sheets may include at least one diffusion sheet, light collection sheet or protection sheet. For example, the optical sheets may be formed of one diffusion sheet and two light collection sheets, or two diffusion sheets and one light collection sheet. The optical sheet may be disposed parallel to the light emitting module 100. Alternatively, the optical sheet may be disposed parallel to a side surface of the light emitting module 100.

The frame 20 may have an open upper surface, and may house the light emitting module 100 and the optical sheets therein. FIG. 3 is a cross-sectional view showing a light emitting module 100 according to a first embodiment of the invention, and hereinafter, the light emitting module 100 according to the first embodiment will be described in detail.

The light emitting module 100 may include a substrate 110, a plurality of light emitting devices 120 disposed on one surface of the substrate 110, and a low-transmittance layer 140 disposed on the substrate 110.

The substrate 110 is a substrate on which the light emitting device 120 is mounted on one surface thereof, and may be a light-transmitting substrate. In particular, the substrate 110 may be the light-transmitting substrate, such as sapphire, PMMA (polymethyl methacrylate), PC (polycarbonate) resin, COP (cyclo olefin polymer), acrylic resin, PE (polyethylene), epoxy resin, glass, or others, without being limited to a specific type. Through the light-transmitting substrate 110, a transparency of the light emitting module 100 may be improved.

One region of the substrate 110 may be formed as a low-transmittance region. Through this, an optical path of light emitted from the light emitting device 120 may be adjusted, and an amount of direct/indirect reflected light shining on a user may be minimized. In addition, a coating layer for reflecting or absorbing light may be disposed on one surface of the substrate 110. The coating layer may include particles such as TiO₂, BaSO₄, SiO₂, or others, which are materials that reflect light. Alternatively, the coating layer may include an absorbing material for absorbing light directed toward a lower surface of the light emitting module 100. The absorbing material may include a pigment such as carbon black, Cr, or the like. Through this, the optical path of light emitted from the light emitting device 120 may be adjusted, and the amount of direct/indirect reflected light shining on the user may be minimized.

The substrate 110 may support the plurality of light emitting devices 120 and may be electrically connected to the plurality of light emitting devices 120 through a conductive region E. More particularly, the light emitting device 120 may be electrically connected to the conductive region E disposed on one surface of the substrate 110. The conductive region E may be formed of conductive material for supplying electricity or an electric signal for driving the light emitting device 120. Metals such as copper, aluminum, silver, tungsten, or others or compounds thereof may be used as a conductive material. In addition, the conductive region E may further include a reflection material for reflecting light to one surface of the light emitting device 120. The reflection material may include Ag, Al, Au, Ni, or others, and a reflectivity thereof may be 60% or more.

In addition, the substrate 110 may include an insulation material to prevent short circuits. The insulation material may include FR-4, CEM-1 or CEM-3 (composite epoxy material), glass paper epoxy, polyamide, glass epoxy, Teflon, ceramic substrates, organic and inorganic composites, or others. The substrate 110 may include a metallic material such as aluminum or copper to improve heat dissipation characteristics of the light emitting device 120.

In addition, the substrate 110 may have a flat shape, but the inventive concepts are not limited thereto. In some embodiments, the substrate 110 may be a strap shape that may be bent according to a shape of the frame 20.

The light emitting device 120 may be provided in one or more numbers in the light emitting module 100. The light emitting device 120 may be a light emitting diode, OLED, or others that emits light. For example, the light emitting device 120 may include a device substrate, a semiconductor layer, and a device electrode. However, the inventive concepts are not limited to a specific structure or shape of the light emitting device 120.

For example, the light emitting device 120 may include sub-pixels that emit blue, green, and red light, respectively. The sub-pixels may be stacked on each other. Alternatively, the sub-pixels may have a form in which the sub-pixels are arranged at regular intervals, without being limited to a specific structure. Still alternatively, the light emitting device 120 may emit white light. In this case, the light emitting device 120 may include a light emitting diode device emitting light of a short wavelength and a phosphor emitting light of a long wavelength. In addition, the light emitting device 120 may be a structure including a color filter that may implement sub-pixels that emit blue, green, and red light in one region of a light emitting portion that emits white light.

In detail, the light emitting device 120 is a light emitting diode device that is disposed on one surface of the substrate 110 and emits light, and various configurations are possible. For example, the light emitting device 120 may include a semiconductor layer formed on a device substrate.

The device substrate may be a growth substrate for growing a gallium nitride semiconductor layer, such as a sapphire substrate, a silicon substrate, a SiC substrate, a spinel substrate, a Ga₂O₃ substrate, or others. The device substrate is not limited to a specific type as long as it is a substrate capable of growing the nitride semiconductor layer thereon. The device substrate may be removed after the semiconductor layer is grown.

In addition, the device substrate may have a roughness on one surface thereof so as to increase light extraction efficiency. Alternatively, the device substrate may have a pattern on one surface thereof so as to increase the light extraction efficiency. The pattern is not limited to a specific shape such as a triangular pyramid, a square pyramid, a polygonal pyramid, a semicircle, a cone with a curved surface, or the like. A partial region of the pattern may include a material of a composition different from that of the device substrate. Through this, the light extraction efficiency may be increased through light refraction effect at a boundary with other materials. In addition, a partial region of a side surface of the device substrate may have a slope with an acute incline.

The semiconductor layer may include a first conductivity type semiconductor layer, a second conductivity type semiconductor layer, and an active layer disposed between the first conductivity type semiconductor layer and the second conductivity type semiconductor layer.

The first conductivity type semiconductor layer may be a semiconductor layer grown on one surface of the device substrate, and may include a phosphide or nitride semiconductor such as (Al, Ga, In) P or (Al, Ga, In) N. In addition, the first conductivity type semiconductor layer may be doped as n-type by including one or more impurities such as Si, C, Ge, Sn, Te, Pb, or others. However, the inventive concepts are not limited thereto, and as another example, the first conductivity type semiconductor layer may be doped with an opposite conductivity type, including a p-type dopant. Furthermore, the first conductivity type semiconductor layer may be formed as a single layer or multiple layers.

The active layer is a light emitting layer disposed on one side of the first conductivity type semiconductor layer, may include a phosphide or nitride semiconductor such as (Al, Ga, In) P or (Al, Ga, In) N, and may be grown on the first conductivity type semiconductor layer using a technique such as MOCVD, MBE, HVPE, or the like. In addition, the active layer may include a quantum well structure (QW) including at least two barrier layers and at least one well layer, and further may include a multi quantum well structure (MQW) including a plurality of barrier layers and a plurality of well layers. A wavelength of light emitted from the active layer may be adjusted by controlling a composition ratio of materials forming the well layer. In this case, the well layers may include a same element in common, for example, In.

The second conductivity type semiconductor layer may be a semiconductor layer disposed on one side of the active layer. The second conductivity type semiconductor layer may include a phosphide or nitride semiconductor such as (Al, Ga, In) P or (Al, Ga, In) N. The second conductivity type semiconductor layer may be doped with a conductivity type opposite to that of the first conductivity type semiconductor layer. For example, the second conductivity type semiconductor layer may be doped as p-type by including an impurity such as Mg.

The light emitting device 120 may have a light-exiting surface formed on a side of the first conductivity type semiconductor layer or the second conductivity type semiconductor layer through which light is emitted. For example, light generated in the active layer may be emitted to the outside through the first conductivity type semiconductor layer, or may be emitted to the outside through the second conductivity type semiconductor layer. A concave-convex structure may be formed on one surface of the first conductivity type semiconductor layer or one surface of the second conductivity type semiconductor layer so as to increase the light extraction efficiency.

In addition, the light emitting device 120 may include a device electrode. The light emitting device 120 may be driven by being electrically connected to an external power source through the device electrode. The device electrode is configured to mount the light emitting device 120 on the conductive region E of the substrate 110, and may be formed of a material suitable thereto. In addition, the device electrode may be in ohmic contact with a semiconductor layer. The device electrode may be formed of, for example, Cr/Pt/Au, or others. One region of the device electrode may include a layer including a material having a reflectivity of 70% or more, such as Ag, Al, or others, for reflecting light to an upper surface of the semiconductor layer.

As another example, the device electrode may be made of a metallic material such as copper, gold, silver, tin, iron, aluminum, or the like. Alternatively, the device electrode may be formed of a compound of the metal, a transparent electrode formed of an oxide such as indium tin oxide (ITO) or manganese oxide, a conductive polymer (PEDOT:PSS, Poly(3,4-ethylenedioxythiophene):poly(styrenesulfonate)), a nanowire such as a silver nanowire or a carbon nanotube, or others.

Meanwhile, the light emitting device 120 according to embodiments are not limited to a specific form, and as another example, the light emitting device 120 may include a stacked light emitting stack in which a plurality of light emitting diodes is stacked and disposed.

The stacked light emitting stacks may include a first light emitting stack, a second light emitting stack, and a third light emitting stack that are sequentially stacked. The second light emitting stack may be disposed over the first light emitting stack, and the third light emitting stack may be sequentially stacked over the second light emitting stack.

Each of the first through third light emitting stacks may include a first conductivity type semiconductor layer, an active layer, and a second conductivity type semiconductor layer. The first through third light emitting stacks may be a light emitting stack that emits red light, a light emitting stack that emits green light, and a light emitting stack that emits blue light, respectively. Accordingly, a stacked light emitting device 120 including the first through third light emitting stacks may display RGB primary colors as pixels.

In addition, the light emitting device 120 may be implemented by being modified into various structures, and may be modified into various structures, such as a flip-chip type, a vertical type, a lateral type, or others.

For example, one of the light emitting devices 120 may be a diode that emits blue light, such as a blue light emitting diode having a peak wavelength within a blue wavelength range, and a difference between the peak wavelength and a dominant wavelength of the blue light emitting diode may be between 2 nm and 15 nm. In detail, the blue light emitting diodes may have the peak wavelength between 430 nm and 475 nm, and may have the dominant wavelength between 460 nm and 480 nm. By keeping the difference between the peak wavelength and the dominant wavelength small, a color deviation may be reduced, thereby resulting in more vivid color expression. The peak wavelength of the blue light emitting diode may be a shorter wavelength than the dominant wavelength. Through this, it is possible to correct luminous efficacy while increasing light energy, thereby reducing a design difficulty.

As another example, one of the light emitting devices 120 may be a diode that emits green light, such as a green light emitting diode having a peak wavelength within a green wavelength range, and a difference between the peak wavelength and a dominant wavelength of the green light emitting diode may be between 5 nm and 20 nm. In detail, the green light emitting diode may have the peak wavelength between 510 nm and 540 nm, and may have the dominant wavelength between 525 nm and 545 nm. By keeping the difference between the peak wavelength and the dominant wavelength small, the color deviation may be reduced, thereby resulting in more vivid color expression. The peak wavelength of the green light emitting diode may be a shorter wavelength than the dominant wavelength. Through this, it is possible to correct the luminous efficacy while increasing light energy, thereby reducing the design difficulty.

As still another example, one of the light emitting devices 120 may be a diode that emits red light, such as a red light emitting diode having a peak wavelength within a red wavelength range, and a difference between the peak wavelength and a dominant wavelength of the red light emitting diode may be between 5 nm and 30 nm. In detail, the red light emitting diode may have the peak wavelength between 620 nm and 640, nm and may have the dominant wavelength between 600 nm and 630 nm. By keeping the difference between the peak wavelength and the dominant wavelength small, the color deviation may be reduced, thereby resulting in more vivid color expression. The peak wavelength of the red light emitting diode may be a longer wavelength than the dominant wavelength. Through this, it is possible to correct the luminous efficacy while increasing light energy, thereby reducing the design difficulty.

The light emitting device 120 in other embodiments may be configured to emit orange light, yellow light, purple light, or ultraviolet light in addition to blue light, green light, and red light.

Meanwhile, the light emitting module 100 may further include an optical layer 130 disposed on the plurality of light emitting devices 120. The optical layer 130 may be positioned between the substrate 110 and the low-transmittance layer 140 to be described later.

The optical layer 130 is formed of a material that transmits light, and may include one or more of PMMA (polymethyl methacrylate), PC (polycarbonate) resin, COP (cyclo olefin polymer), acrylic resin, silicone resin, PE (polyethylene), PVB (polyvinylbutyral), PDMS (polydimethylsiloxane), epoxy resin, and glass or quartz.

The optical layer 130 may cover the light emitting device 120, and the light emitting device 120 may be disposed over, under, or therebetween of the optical layer 130.

The optical layer 130 may include a light transmitting region including light-scattering particles for scattering light. The light scattering particles may include inorganic particles such as silica (SiO₂), titanium dioxide (TiO₂), alumina (Al₂O₃), calcium carbonate (CaCO₃), magnesium fluoride (MgF₂), or others. Moreover, the optical layer 130 may include particles formed of an organic material such as polymethyl methacrylate (PMMA) or polystyrene (PS).

The low-transmittance layer 140 is configured to be disposed on the light-exiting surface side of the substrate 110, and various configurations are possible. For example, the low-transmittance layer 140 may be disposed on one surface of the optical layer 130. Light emitted from the light emitting device 120 may pass through the optical layer 130 and be emitted to the outside through the low-transmittance layer 140. A thickness of the low-transmittance layer 140 may be larger than those of the stacked light emitting stacks. Through this, sufficient light blocking effect may be secured. In addition, a pattern may be printed on one region of the low-transmittance layer 140 for aesthetic effect.

The low-transmittance layer 140 may include regions with different light transmittances. For example, the low-transmittance layer 140 may include a low-transmittance region having a light transmittance of less than 50% and a light transmitting region having a light transmittance higher than that of the low-transmittance region. The light transmitting region may be provided in a plurality of numbers. The light transmittance of the light transmitting region may be 50% or more.

The light transmitting region may be a region in which a perforation P passing through the low-transmittance layer 140 is formed. The region in which the perforation P is formed may be defined as the light transmitting region, and a remaining region excluding the perforation P may be defined as the low-transmittance region.

The low-transmittance layer 140 may be a layer including an optical material that absorbs or reflects light. For example, the low-transmittance layer 140 may be a layer including a reflection material. The reflection material may include a metallic material such as aluminum, silver (Ag), copper (Cu), or others. Alternatively, the low-transmittance layer 140 may include a material that absorbs or blocks light. The light absorbing material may include a dye, a pigment, a light absorbing nano structure, or others.

For example, the low-transmittance layer 140 may have a metallic mirror film form. Alternatively, the low-transmittance layer 140 may be a reflective layer in which aluminum is deposited on polyester or polycarbonate. Still alternatively, the low-transmittance layer 140 may include silica (SiO₂) and yttrium oxide (Y₂O₃) as an inorganic nano-coating film that controls a reflection and transmission of light with specific nano-materials.

In addition, the low-transmittance layer 140 may include an optical multilayer thin film layer. The multilayer thin film layer may be an anti-reflective layer in which several layers (e.g., SiO₂, TiO₂) having different refractive indices are stacked, a high reflective layer in which a high refractive index material (HfO₂, TiO₂) and a low refractive index material (SiO₂) are repeatedly stacked, a spectral filter layer, an optical multilayer layer that controls an optical interference effect with a multilayer thin film, or others.

The low-transmittance region and the light transmitting region may have different densities. The low-transmittance region may be disposed at a density of optical material higher than that of the light transmitting region. Through this, a contrast of the light emitting module 100 may be increased. Furthermore, the light transmitting region may be a region without an optical material. A transparent material may be further disposed in the light transmitting region. That is, the transparent material may be disposed within the perforation P. Through this, light loss may be minimized and radiation efficiency may be increased.

Meanwhile, the low-transmittance region and the light transmitting region may have different optical characteristics. For example, the low-transmittance region and the light transmitting region may have different reflectances.

Referring back to FIG. 3, the light transmitting region, i.e., the perforation P, may have a regular arrangement. Through this, the design difficulty may be reduced. The light transmitting region may have an arrangement corresponding to that of the light emitting device 120. For example, one light emitting device 120 may be disposed to correspond to each of the light transmitting regions. The light transmitting region may be positioned to overlap the light emitting device 120. Through this, a loss of light emitted from the light emitting device 120 may be minimized, thereby increasing an efficiency of the light emitting module 100.

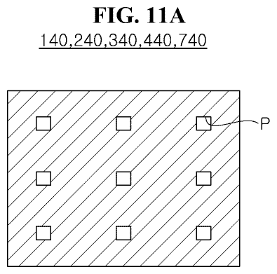

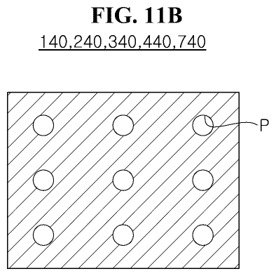

FIG. 11A is a plan view showing the low-transmittance layer 140 according to an embodiment, in which the light transmitting regions are arranged in a regular pattern. The perforation P forming the light transmitting region may have various shapes, and for example, it may be rectangular. However, the inventive concepts are not limited thereto, and the perforation P may be formed in various shapes, such as a circular shape as shown in FIG. 11B or the like. The shape of the perforation P is not limited to a specific shape.

In addition, FIG. 11A exemplarily shows that the perforations P are regularly arranged in a matrix form, but the arrangement of the perforations P may be modified into various other patterns. That is, the light transmitting regions are not limited to being arranged regularly in a mesh shape, and it is also possible for the light transmitting regions to be arranged in irregular regions. In addition, a distance between adjacent perforations P may be smaller than a distance between adjacent light emitting devices 120. Through this, it is possible to effectively conceal the perforation P such that it is not visually recognized by a user from the outside, thereby improving an aesthetic appearance of an entire light emitting module 100.

In addition, the distance between the adjacent perforations P may be longer than a peak wavelength of emitted light of the light emitting device 120. In addition, the distance between the adjacent perforations P may have an interval that is an integer multiple of at least one peak wavelength among the peak wavelengths of emitted light of the light emitting device 120. Through this, it is possible to reduce destructive interference of emitted light and increase the light extraction efficiency.

In addition, an area of the low-transmittance region excluding the light transmitting region may have an area larger than an area occupied by the light emitting devices 120. In addition, the low-transmittance region may have a larger than the light transmitting region. Through this, it is possible to increase reflectivity. In addition, through this, it is possible to prevent the user from perceiving the light transmitting region, i.e. the perforation P, thereby increasing the contrast.

Meanwhile, a cross-sectional diameter of the perforation P forming the light transmitting region may be set in various ways, and for example, it may be larger than a width of the corresponding light emitting device 120. Through this, the loss of light emitted from the light emitting device 120 may be minimized, thereby increasing the radiation efficiency. The cross-sectional diameter of the perforation P may be in a range of 50% to 90% of a cross-sectional length of the light emitting device 120 on a same plane. Through this, the light emitting device 120 may be effectively concealed such that it is not visible from the outside, thereby improving the aesthetic appearance of the entire light emitting module 100. For example, when the cross-sectional length of the light emitting device 120 is 400 μm, the cross-sectional diameter of the perforation P may be 300 μm or less. The cross-sectional diameter of the perforation P may be set differently depending on other factors such as a type of display, the width of the light emitting device 120, and others.

Referring back to FIG. 3, a luminance of light L1 passing through the light transmitting region among light emitted from the light emitting device 120 may have a luminance higher than that of light L2 passing through the low-transmittance region. For example, the luminance of the L1 may be at least 1.5 times of the luminance of the L2. Through this, the contrast of the light emitting module 100 may be increased.

In addition, some of light emitted from the light emitting device 120 may cause constructive and destructive interferences after passing through the low-transmittance layer 140. Through this, light from the light transmitting region and light from the low-transmittance region may become destructive/constructive to each other over a certain distance, so that a difference in luminance between two regions may be more than double. Through this, it is possible to implement higher clarity.

Referring again to FIG. 3, the low-transmittance layer 140 may be disposed on the light-exiting surface side of the light emitting device 120. As the low-transmittance layer 140 is disposed over the optical layer 130, the low-transmittance layer 140 may be spaced apart from the light emitting device 120.

A distance between the low-transmittance layer 140 and the light emitting device 120 may be greater than a height of the light emitting device 120. The distance between the low-transmittance layer 140 and the light emitting device 120 may be 3 times or more and less than 7 times of the height of the light emitting device 120. Through this, a light path may be secured to increase the light extraction efficiency, and the light emitting device 120 may be effectively concealed such that it is not visible from the outside, thereby improving the aesthetic appearance of the entire light emitting module 100.

A distance from one surface of the light emitting device 120 to a lower surface of the low-transmittance layer 140 may be substantially equal to a distance from one surface of the light emitting device 120 to an upper surface of the optical layer 130. That is, the lower surface of the low-transmittance layer 140 and the upper surface of the optical layer 130 may be positioned at a same height. When the low-transmittance layer 140 and the lower surface and the upper surface of the optical layer 130 are disposed in close contact, total internal reflection at an interface may be reduced, thereby increasing the light extraction efficiency.

In addition, a refractive index in the light transmitting region may be lower than that of the optical layer 130. Through this, it is possible to increase a light extraction efficiency in the light transmitting region, i.e., the region in which the perforation P is formed. In addition, the refractive index in the light transmitting region may be lower than a refractive index on an upper surface of the light emitting device 120. Through this, it is possible to increase the light extraction efficiency.

A refractive index in the low-transmittance region may be higher than that of the optical layer 130. Through this, a path of light towards the low-transmittance region may be adjusted. In addition, the refractive index in the low-transmittance region may be lower than the refractive index on the upper surface of the light emitting device 120. By utilizing a total internal reflection effect through a change in refractive index, the light emitting device 120 may be effectively concealed such that it is not visible from the outside, thereby improving the aesthetic appearance of the entire light emitting module 100.

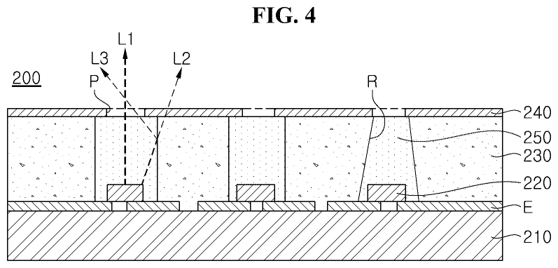

Next, FIG. 4 is a cross-sectional view showing a light emitting module 200 according to a second embodiment of the invention, and hereinafter, the light emitting module 200 according to the second embodiment will be described in detail, focusing on differences from the first embodiment.

The light emitting module 200 may be configured identically or similarly to the light emitting module 100 of the first embodiment, except that it includes a first optical layer 250 and a second optical layer 230 instead of a single optical layer 130.

In detail, the light emitting module 200 may include the first optical layer 250 covering the light emitting device 220 between a substrate 210 and a low-transmittance layer 240, and the second optical layer 230 surrounding the first optical layer 250. The second optical layer 230 may be disposed between the light emitting devices 220. Through this, it is possible to reduce optical interference between light emitting devices 220 and improve color clarity.

The first optical layer 250 and the second optical layer 230 may have different optical characteristics. For example, refractive indices of the first optical layer 250 and the second optical layer 230 may be different from each other. The first optical layer 250 may have the refractive index higher than that of the second optical layer 230. Through this, it is possible to adjust an optical path through a total internal reflection effect at an interface between the first optical layer 250 and the second optical layer 230, thereby increasing the light extraction effect.

To further increase the light extraction efficiency, a boundary surface where the first optical layer 250 and the second optical layer 230 adjoin may form a reflection surface on which light emitted from the light emitting device 220 is reflected. Light emitted from the light emitting device 220 may be totally internally reflected on the reflection surface, and thus the light extraction efficiency may be increased.

By disposing a light transmitting region, i.e., a perforation P, to correspond to an upper portion of the first optical layer 250, a light extraction efficiency through the first optical layer 250 may be increased. To increase the refractive index of the first optical layer 250, particles such as silica (SiO₂) may be further included in the first optical layer 250.

As another example, the second optical layer 230 may have a reflectance higher than that of the first optical layer 250. The second optical layer 230 may further include particles that increase reflectivity to increase light reflectance. For example, the second optical layer 230 may include particles such as TiO₂, BaSO₄, SiO₂, or others to increase the reflectivity. In addition, the second optical layer 230 may further include refractive index improving particles such as a hollow filler having an air layer inside the filler. Through this, it is possible to induce reflection at the boundary surface between two optical layers 230 and 250, and thus, the optical path may be adjusted. In this case, to increase the light extraction efficiency, the perforation P of the low-transmittance layer 240 may be disposed to correspond to the first optical layer 250 having the high refractive index.

For example, a cross-sectional width of the first optical layer 250 may be constant. As another example, the cross-sectional width of the first optical layer 250 may vary toward the perforation P. That is, the cross-sectional width of the first optical layer 250 may vary depending on a distance from one surface of the substrate 210. As still another example, the first optical layer 250 having a constant cross-sectional width may be disposed along with the first optical layer 250 having a varying constant cross-sectional width.

For example, the cross-sectional width of the first optical layer 250 may decrease or increase toward the perforation P. When the cross-sectional width of the first optical layer 250 varies, the boundary surface between the first optical layer 250 and the second optical layer 230 may form a slope.

In addition, a maximum width of the first optical layer 250 may be larger than a cross-sectional diameter of the perforation P. Through this, the light emitting device 220 may be effectively concealed such that it is not visible from the outside, thereby improving an aesthetic appearance of the entire light emitting module 200. Alternatively, an upper end width adjacent to the low-transmittance layer 240 of the first optical layer 250 may be larger than the cross-sectional diameter of the perforation P. Through this, light emitted from the light emitting device 220 may be guided to a perforation P region, thereby increasing the light extraction efficiency.

As described above, the path of light movement may be adjusted by designing the cross-sectional width of the first optical layer 250 to increase a luminance in the light transmitting region.

In FIG. 4, luminance of light L1 and L3 passing through the light transmitting region among light emitted from the light emitting device 220 may have a luminance higher than that of light L2 passing through a low-transmittance region. A portion of light L3 directed toward the low-transmittance region is reflected on the boundary surface between the first optical layer 250 and the second optical layer 230 and is emitted to the outside through the light transmitting region, thereby further increasing the luminance in the light transmitting region.

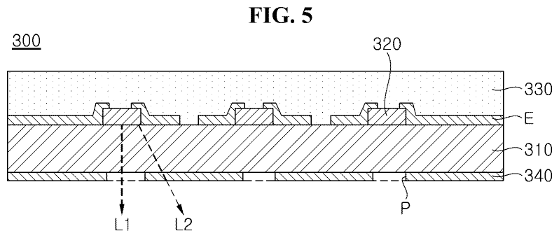

Next, FIG. 5 is a cross-sectional view showing a light emitting module 300 according to a third embodiment of the invention, and hereinafter, the light emitting module 300 according to the third embodiment will be described in detail, focusing on differences from the first and second embodiments.

The light emitting module 300 may be configured similarly to the light emitting modules 100 and 200 of the first and second embodiments, except that a low-transmittance layer 340 is disposed on the other surface opposite to one surface of a substrate 310 on which a light emitting device 320 is disposed. In this case, the surface of the substrate 310 facing away from the light emitting device 320 may be c a light-exiting surface from which light from the light emitting device 320 is emitted.

In FIG. 5, the low-transmittance layer 340 may be disposed on a lower portion of the light emitting device 320, that is, on the other surface, which is a side surface opposite to one surface of the substrate 310 on which the light emitting device 320 is disposed. As the substrate 310 is disposed between the low-transmittance layer 340 and the light emitting device 320, a vertical distance from one surface of the light emitting device 320 to the low-transmittance layer 340 may be substantially equal to a height of the substrate 310. In this case, a vertical distance of the substrate 310 may be greater than the height of the light emitting device 320. Through this, the light emitting device 320 may be protected from the outside. In addition, the vertical distance (of height) of the substrate 310 may be greater than a distance between the light emitting devices 320. By using this, the light emitting device 320 may be effectively concealed such that it is not visible from the outside, and thus, an aesthetic appearance of an entire light emitting module 300 may be improved. In addition, a thickness of the low-transmittance layer 340 may be thinner than the vertical distance of the substrate 310. Through this, an optical path may be secured, thereby increasing light extraction efficiency.

In FIG. 5, light may pass through the substrate 310 and be emitted to the outside through the other surface of the substrate 310. In this case, the substrate 310 may have transparency higher than that of an optical layer 330. The optical layer 330 may include a filler such as a reflection material, for example, TiO, BaSO₄, or others to increase reflectance. A density of the filler included in the optical layer 330 may be higher than that of a filler included in the substrate 310. The density may be compared with a content or wt % of an included filler based on an area equal to an area of the light emitting device 320. The optical layer 330 may have a thickness larger than that of the substrate 310. Through this, the optical path may be adjusted.

A conductive region E of the substrate 310 may be disposed on an upper surface and a side surface of the light emitting device 320. Through this, it is possible to reflect light emitted from the side surface of the light emitting device 320, thereby increasing the light extraction efficiency. In this case, the substrate 310 may be made of glass such as highly transparent soda-lime glass, alkali-free glass, borosilicate glass, quartz, or the like, or a plastic film such as PET (polyethylene terephthalate), PEN (polyethylene naphthalate), or PI (polyimide). In addition, a sapphire substrate may be used to achieve both transparency and hardness.

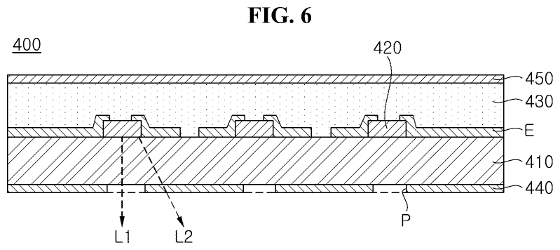

Next, FIG. 6 is a cross-sectional view showing a light emitting module 400 according to a fourth embodiment of the invention, and hereinafter, the light emitting module 400 according to the fourth embodiment will be described in detail, focusing on differences from the first through third embodiments.

The light emitting module 400 may be configured identically or similarly to that of the third embodiment, except that it further includes a reflective layer 450.

The reflective layer 450 is a layer disposed on the plurality of light emitting devices 420 of a substrate 410, and various configurations are possible. The reflective layer 450 may be disposed on one surface of the optical layer 430.

The reflective layer 450 may reflect light passing through the optical layer 430 in a direction toward a low-transmittance layer 440. Through this, a luminance measured from a low-transmittance layer 440 side may be higher than a luminance measured from the reflective layer 450.

In this case, a controller IC may be further disposed between the reflective layer 450 and the light emitting device 420. The controller IC may be electrically connected to the light emitting device 420 to control an operation of the light emitting device 420. The controller IC may be disposed to be overlapped with the light emitting device 420 in a cross-sectional view. Through this, a non-light emitting region may be reduced, and a light emitting region may be expanded, thereby increasing a luminance of the light emitting module 400.

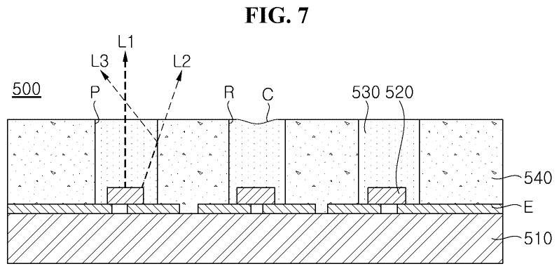

Next, FIG. 7 is a cross-sectional view showing a light emitting module 500 according to a fifth embodiment of the invention, and hereinafter, the light emitting module 500 according to the fifth embodiment will be described in detail, focusing on differences from the first through fourth embodiments.

The light emitting module 500 may be configured identically or similarly to those of the first through fourth embodiments, except that an optical layer 530 is disposed within a perforation P of a low-transmittance layer 540.

In FIG. 7, the low-transmittance layer 540 may be disposed on one surface of a substrate 510 and may form a space to accommodate a light emitting device 520 in the perforation P. The optical layer 530 may be disposed within the perforation P to cover the light emitting device 520. That is, a region in which the perforation P of the low-transmittance layer 540 is formed may be substantially same as a region in which the optical layer 530 is formed.

A height of the low-transmittance layer 540 may be substantially the same as that of the optical layer 530. In addition, a lower region of the low-transmittance layer 540 may be disposed at a same height as a lower region of the optical layer 530 on one surface of the substrate 510.

Meanwhile, a partial region of the optical layer 530 may have curvature. For example, the optical layer 530 corresponds to a light transmitting region, and one surface thereof may form a light-exiting surface. In this case, the light-exiting surface of the optical layer 530 may correspond to an upper surface of the optical layer 530, and in this case, the light-exiting surface of the optical layer 530 may be a curved surface.

For example, the light-exiting surface may have a concave, sunken shape toward the light emitting device 520. That is, in a partial region of the optical layer 530, the height of the optical layer 530 may be lower than that of the low-transmittance layer 540. Light extraction efficiency may be increased through a curved shape of the optical layer 530. In addition, since the light-exiting surface of the optical layer 530 has a concave shape downward, a partial region of the optical layer 530 is positioned below the low-transmittance layer 540, so that the light extraction efficiency may be improved without the optical layer 530 being recognized by a user's eyes.

Referring back to FIG. 7, a cross-sectional width of the optical layer 530 matches a cross-sectional width of the perforation P, and may have a constant value depending on a position thereof. However, the inventive concepts are not limited thereto, and the cross-sectional width of the optical layer 530 or the cross-sectional width of the perforation P may vary depending on a distance from one surface of the substrate 510.

In a case that the cross-sectional width of the perforation P has a constant shape as shown in FIG. 7, a design difficulty may be reduced by simplifying the shapes of the low-transmittance layer 540 and the optical layer 530.

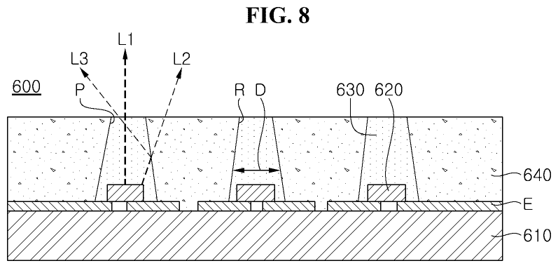

Next, FIG. 8 is a cross-sectional view showing a light emitting module 600 according to a sixth embodiment of the invention, and hereinafter, the light emitting module 600 according to the sixth embodiment will be described in detail, focusing on differences from the first through fifth embodiments.

The light emitting module 600 may be configured identically or similarly to that of the fifth embodiment, except that the cross-sectional width of the optical layer 630 or a cross-sectional width of a perforation P varies depending on a distance from one surface of a substrate 610.

Referring to FIG. 8, a perforation P of a low-transmittance layer 640 may have a cross-sectional width that may vary depending on a position thereof. The cross-sectional width of the perforation P may decrease as disposed further away from a light emitting device 620. Accordingly, the cross-sectional width of the optical layer 630 may decrease as it gets farther from the light emitting device 620.

Accordingly, a cross-sectional width at an upper portion of the optical layer 630 may be smaller than a cross-sectional width at a lower portion of the optical layer 630. The optical layer 630 may have a width that is larger in a region adjacent to the light emitting device 620 than in a region far from the light emitting device 620. Through this, light receiving efficiency may be increased in the lower portion adjacent to the light emitting device 620, and the cross-sectional width of the optical layer 630 is narrowed on a side of a light-exiting surface where light is emitted, thereby improving light extraction efficiency without the optical layer 630 being recognized by a user's eyes.

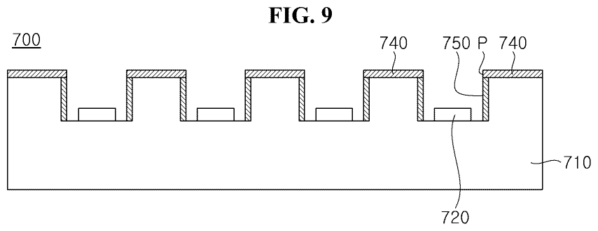

Next, FIG. 9 is a cross-sectional view showing a light emitting module 700 according to a seventh embodiment of the invention, and hereinafter, the light emitting module 700 according to the seventh embodiment will be described in detail, focusing on differences from the first through sixth embodiments.

The light emitting module 700 may include a substrate 710, a plurality of light emitting devices 720 disposed on one surface of the substrate 710, and a low-transmittance layer 740 including a plurality of perforations P disposed on one surface of the substrate 710 and exposing the plurality of light emitting devices 720.

In this case, the substrate 710 is a light-transmitting substrate such as sapphire and may include a side wall portion that forms a cavity in which the plurality of light emitting devices 720 is disposed. The side wall portion is configured to be formed integrally with the substrate 710, and for example, may be formed by etching one surface of the substrate 710.

The side wall portion is a side wall structure that protrudes upward from one surface of the substrate 710, and the cavity may correspond to a space surrounded by the side wall portion. The cavity may be formed corresponding to each of the light emitting devices 720.

A side surface of the side wall portion may form a reflection surface on which light from the light emitting device 720 is reflected. To this end, the light emitting module 700 may further include a side reflective layer (or side reflector) 750 disposed on an inner surface of the cavity.

For example, the side reflector 750 may include a metallic layer such as Al, Ag, Cr, Ni, Ti, Pt, or others. As another example, the side reflector 750 may be a multi-layer DBR layer formed of different materials.

The side reflector 750 may be formed in various thicknesses, and for example, may have a thickness of 3 μm to 50 μm.

The low-transmittance layer 740 may be disposed on the side wall portion. The low-transmittance layer 740 is disposed on an upper surface of the side wall portion, and the perforation P is disposed correspondingly on an open upper surface of the cavity, so that a light transmitting region may be formed in the perforation P, and a low-transmittance region may be formed in a region excluding the perforation P.

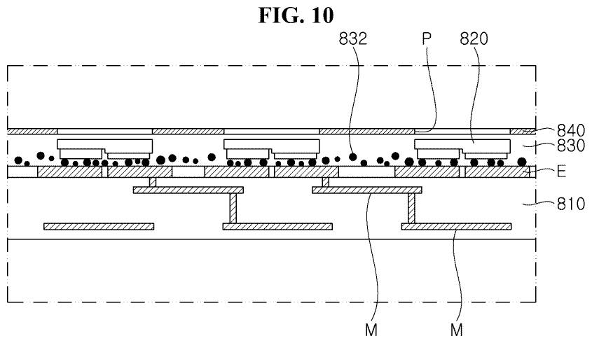

Next, FIG. 10 is a cross-sectional view showing a light emitting module 800 according to an eighth embodiment of the invention, and hereinafter, the light emitting module 800 according to the eighth embodiment will be described in detail, focusing on differences from the first through seventh embodiments.

The light emitting module 800 may be configured in a same or similar manner as those of the first through seventh embodiments, except that it includes a spacer 830 for physically connecting a light emitting device 820 to a substrate 810. The spacer 830 may have optical characteristics identical to or similar to those of the optical layer described above.

The spacer 830 may include a plurality of particles 832 and a polymer layer surrounding the plurality of particles. The particles 832 may be dispersed within the spacer 830. The plurality of particles 832 may include a conductive material, and may electrically connect the light emitting device 820 and the substrate 810. The light emitting device 820 is connected to a conductive region E of the substrate 810 through a conductive particle 832, and the conductive region E may be connected to a metal M within the substrate 810.

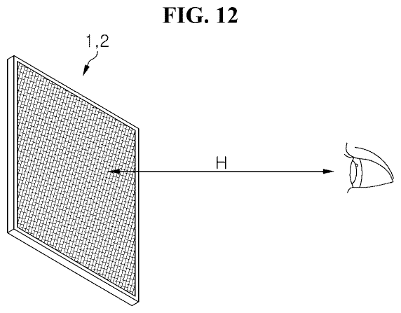

Next, FIG. 12 is a drawing illustrating a distance relationship between a light emitting system 1 or 2 including the light emitting module according to an embodiment of the invention and a user.

Depending on a type of the light emitting system 1 or 2, the user may use the light emitting system 1 or 2 from a specific distance. Herein, the specific distance may be defined as a preset viewing distance H for a specific light emitting system 1 or 2. The viewing distance H may vary depending on an application of the light emitting system 1 or 2.

Depending on the viewing distance H, shapes and sizes of the light transmitting regions (or perforations P) and the low-transmittance regions of the low-transmittance layers 140, 240, 340, 440, 540, 640, 740, and 840 may be determined.

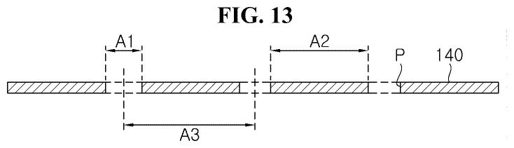

Referring to FIG. 13, the light transmitting regions (or the perforations P) of the low-transmittance layers 140, 240, 340, 440, 540, 640, 740, and 840 may have a cross-sectional length A1 with respect to a cross-section. The cross-sectional length A1 may be set according to a viewing angle (α) and the viewing distance H. Herein, the viewing angle (α) may be a general viewing angle of the human eye, which may be 1 arcminute (=0.000291 radians).

In this case, the cross-sectional length A1 may be defined as in Equation 1 below.

$$Cross - sectional length A 1 \leq 2 \times viewing distance H \times tan ( α / 2 ) \qquad [ Equation 1 ]$$

As the viewing angle (α) has a very small value, the cross-sectional length A1 may be designed to have a value less than or equal to a value obtained by multiplying the viewing angle (α) by the viewing distance H.

For example, in a case of display apparatuses for home appliances such as monitors or smart mirrors, since a typical viewing distance H is less than 1 m, the cross-sectional length A1 may be less than 291 μm.

In addition, adjacent two light transmitting regions (or the perforations P) may be spaced apart by a center-to-center distance A3. The center-to-center distance A3 may also vary depending on the viewing distance H.

In addition, the low-transmittance region may have a cross-sectional length A2 on one section, and the cross-sectional length A2 may have a value greater than A1 and less than A3. The cross-sectional length A2 may also vary depending on the viewing distance H.

Referring to Table 1 below, depending on the type of the light emitting system 1 or 2, the viewing distance H, the cross-sectional length A2 of the low-transmittance region, and the cross-sectional length A1 of the light transmitting region (or the perforation P) may be designed within the following ranges.

TABLE 1

| Light | Viewing | Sub- | | | |
|---|---|---|---|---|---|
| emitting | distance | pixel | PPI (pixel | | |
| system | (H, cm) | Size (μm) | per inch) | A1(mm) | A2(mm) |
| VR | 2~4 | 3-5 | 600-1200 | 0.0058~ | 0.0212~ |
| | | | | 0.012 | 0.0423 |
| Smart phone | 30~50 | 30-50 | 300-600 | 0.07~ | 0.0423~ |
| | | | | 0.116 | 0.0847 |
| Smart watch | 25~40 | 20-40 | 250-350 | 0.087~ | 0.0726~ |
| | | | | 0.146 | 0.1016 |
| Monitor, | 50~80 | 50-100 | 100-300 | 0.146~ | 0.0847~ |
| Display for | | | | 0.233 | 0.2540 |
| home | | | | | |
| appliance | | | | | |
| TV | 200~300 | 100-200 | 50-200 | 0.582~ | 0.127~ |
| | | | | 0.873 | 0.508 |
| Scoreboard | 10000 or | | 10-50 | 2.910~ | 0.508~ |
| | more | | | | 2.54 |

Herein, the cross-sectional length A2 of the low-transmittance region may be calculated by dividing 25.4 by PPI. In addition, the center-to-center distance A3 of the adjacent two light transmitting regions (or the perforations P) may be calculated by adding A1 and A2.

Although various application examples using the light emitting modules 100, 200, 300, 400, 500, 600, 700, and 800 according to embodiments of the invention have been described above, the application examples of the present invention are not limited to the matters described above. The light emitting modules 100, 200, 300, 400, 500, 600, 700, and 800 according to the embodiments may also be used for displays, and applied to various apparatuses such as vehicle rear surfaces or lighting apparatuses.

Further, a polymer dispersed liquid crystal (PDLC) may be disposed in one region of the low-transmittance layers 140, 240, 340, 440, 540, 640, 740, and 840. The polymer dispersed liquid crystal (PDLC) may have a transparency thereof adjusted by an electrical signal. Through this, the light emitting devices 120, 220, 320, 420, 520, 620, 720, and 820 may be effectively concealed according to the electric signal such that they are not visible from the outside, and accordingly, the aesthetic appearances of the entire light emitting modules 100, 200, 300, 400, 500, 600, 700, and 800 may be improved. In this case, the polymer dispersed liquid crystal (PDLC) may form a channel portion in which a dye or pigment is disposed. A size of the channel portion may be smaller than those of the light emitting devices 120, 220, 320, 420, 520, 620, 720, and 820. Through this, it is possible not to obstruct the optical path in a transparent mode, thereby increasing the light extraction efficiency. A thickness of the polymer dispersed liquid crystal (PDLC) may be smaller than those of the optical layer 130, 230, 430, 530, 630, and 730. Through this, the light extraction efficiency may be increased by sufficiently securing the optical paths in the optical layers 130, 230, 430, 530, 630, and 730.

A light emitting module according to embodiments of the invention implements shapes or letters on a mirror, an exterior, glass, or others.

A light emitting module according to embodiments of the invention implements a clear image by improving a contrast ratio.

A light emitting module according to embodiments of the invention improves visibility by improving reflectance.

A light emitting module according to embodiments of the invention provides clear image quality without image distortion.

A light emitting module according to embodiments of the invention displays accurate colors by improving color reproducibility.

A light emitting module according to embodiments of the invention improves surface quality such as surface flatness, bonding, curvature, reflection, or others.

A light emitting module according to embodiments of the invention has high light extraction efficiency.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A light emitting module, comprising:
a substrate;
a plurality of light emitting devices disposed on one surface of the substrate; and
a low-transmittance layer disposed on a light-exiting surface side of the substrate,
wherein the low-transmittance layer includes a low-transmittance region having a light transmittance of less than 50% and a light transmitting region having a light transmittance higher than that of the low-transmittance region.

2. The light emitting module of claim 1, wherein the low-transmittance layer includes a perforation passing through the low-transmittance layer, and the perforation corresponds to the light transmitting region.

3. The light emitting module of claim 2, wherein a cross-sectional diameter of the perforation is in a range of 50% to 90% of a cross-sectional length of the light emitting device.

4. The light emitting module of claim 1, wherein the low-transmittance region and the light transmitting region have different reflectances.

5. The light emitting module of claim 1, wherein the light transmitting region overlaps the light emitting device.

6. The light emitting module of claim 1, wherein the low-transmittance layer is disposed on the other surface of the substrate.

7. The light emitting module of claim 6, further comprising a reflective layer disposed on the plurality of light emitting devices on one side of the substrate.

8. The light emitting module of claim 7, further comprising an optical layer covering the plurality of light emitting devices,
wherein the reflective layer is disposed on the optical layer.

9. The light emitting module of claim 1, further comprising an optical layer disposed on the plurality of light emitting devices.

10. The light emitting module of claim 9, wherein the optical layer includes a first optical layer covering the light emitting device and a second optical layer surrounding the first optical layer.

11. The light emitting module of claim 10, wherein a boundary surface between the first optical layer and the second optical layer forms a reflection surface to reflect light emitted from the light emitting device.

12. The light emitting module of claim 10, wherein the first optical layer and the second optical layer have different optical characteristics.

13. The light emitting module of claim 12, wherein a reflectance of the second optical layer is greater than that of the first optical layer.

14. The light emitting module of claim 10, wherein a cross-sectional width of the first optical layer varies depending on a distance from one surface of the substrate.

15. A light emitting module, comprising:
a substrate;
a plurality of light emitting devices disposed on one surface of the substrate;
a low-transmittance layer including a plurality of perforations disposed on one surface of the substrate and exposing the plurality of light emitting devices; and
an optical layer disposed within the perforation.

16. The light emitting module of claim 15, wherein a light-exiting surface of the optical layer is curved.

17. The light emitting module of claim 15, wherein a cross-sectional width of the perforation varies depending on a distance from one surface of the substrate.

18. A light emitting module, comprising:
a substrate;
a plurality of light emitting devices disposed on one surface of the substrate; and
a low-transmittance layer including a plurality of perforations disposed on one surface of the substrate and exposing the plurality of light emitting devices,
wherein:
the substrate includes a side wall portion defining a cavity to which the light emitting device is disposed; and
the low-transmittance layer is disposed on the side wall portion.

19. The light emitting module of claim 18, further comprising a side reflective layer disposed on an inner surface of the cavity.

20. The light emitting module of claim 19, wherein the side reflective layer is a DBR layer.
